(19) United States
(12) Patent Application Publication
(10) Pub. No.: US 2013/0294146 A1
(43) Pub. Date: Nov. 7, 2013

(54) RESISTIVE MEMORY DEVICE AND METHOD OF FABRICATING THE SAME

(71) Applicants: Jeong Hwan KIM, Icheon-si Gyeonggi-do (KR); Sai Hyung JANG, Icheon-si Gyeonggi-do (KR); Myung Sun SONG, Icheon-si Gyeonggi-do (KR)

(72) Inventors: Jeong Hwan KIM, Icheon-si Gyeonggi-do (KR); Sai Hyung JANG, Icheon-si Gyeonggi-do (KR); Myung Sun SONG, Icheon-si Gyeonggi-do (KR)

(73) Assignee: SK HYNIX INC., Icheon-si Gyeonggi-do (KR)

(21) Appl. No.: 13/588,476

(22) Filed: Aug. 17, 2012

(30) Foreign Application Priority Data
May 4, 2012 (KR) 10-2012-0047464

(51) Int. Cl. G11C 11/21; H01L 21/02; G11C 5/02

(52) U.S. Cl. 365/148; 438/382; 257/E21.004

(57) ABSTRACT

A resistive memory device according to an embodiment includes a plurality of word lines extended and formed in a first direction; a global word line signal line extended substantially in the first direction, formed substantially in a layer substantially identical with the word lines, and interposed substantially between a designated number of the word lines; a plurality of bit lines extended and formed in a second direction tilted at an angle with the first direction; a plurality of normal cells connected substantially between the word line and the bit line; and a plurality of dummy cells connected substantially between the global word line signal line and the bit line.

### CROSS-REFERENCE TO RELATED APPLICATION

The present application claims priority under 35 U.S.C. §119(a) to Korean application number 10-2012-0047464, filed on May 4, 2012, in the Korean Intellectual Property Office, which is incorporated herein by reference in its entirety.

### BACKGROUND

1. Technical Field

The present invention generally relates to memory devices, resistive memory devices, and a method of fabricating the same.

2. Related Art

As well known in the art, a semiconductor memory array includes numerous unit memory cells. Furthermore, when accessing a specific unit memory cell for operating a semiconductor memory device, an external address is decoded and a relevant word line and bit line are enabled.

Research has been and is being carried out on various nonvolatile memory devices for replacing the existing flash memory. Typical examples of the nonvolatile memory devices may include magnetic random access memory (MRAM), phase-change random access memory (PRAM), and resistance random access memory (RRAM), etc.

In particular, a memory device having data storage materials interposed between a bottom electrode and a top electrode, such as in a PRAM or RRAM, has a memory cell array having a cross-point array structure. The cross-point array structure refers to a structure in which a plurality of bottom electrodes and a plurality of top electrodes are formed to cross each other and a memory node is formed at the crossing point of the top and bottom electrodes.

FIG. 1 is a schematic diagram of a known resistive memory device.

As shown in FIG. 1, the resistive memory device 10 includes a plurality of unit cell arrays 110, a sub-row decoder (SX-DEC) 120, a main row decoder (MX-DEC) 130, a column decoder (Y-DEC) 140, a write driver (W/D) and sense/amplifier (S/A) block 150, a global bit line switch (GYSW) 160, a local bit line switch (LYSW) 170, and a local word line switch (LXSW) 180.

Local word lines WL<0:n> and global word lines GX<0:1> connected to resistive memory cells that form each of the unit cell arrays 110 are connected to the LXSW 180. Memory cells to be accessed by the LXSW 180 are selected according to a result of decoding performed by the MX-DEC 130 and the SX-DEC 120.

The global word lines GX<0:1> are disposed in a plurality of the local word lines. For example, 16 local word lines may be controlled by two global word lines.

FIG. 2 shows the construction of a local word line switch.

As shown in FIG. 2, the local word line switch includes first to third switching elements P1, N1, and N2, respectively, coupled in series between a high voltage supply terminal VPPX and a ground terminal VSS.

The first switching element P1 is a power supply element and driven in response to a global word line signal GX. The first switching element P1 supplies a high voltage to a word line WL.

The second switching element N1 forms or blocks a sensing current or write current path in response to the global word line signal GX.

The third switching element N2 is driven in response to a local word line signal LXB.

The global word line signal GX and the local word line signals LX and LXB are external signals, and the address of a word line is determined by a combination of the signals.

In case of a resistive memory device, in particular, a phase change memory device, GST, that is, where data storage materials are disposed between word lines and bit lines. Thus, additional circuits may be formed under the word line. Accordingly, the size of the memory device may be reduced because the second and the third switching elements N1 and N2 forming the local word line switch are disposed under the word lines. In this case, the first switching element P1 is disposed outside a memory cell array.

FIG. 3 a diagram illustrating the disposition of a local word line switch in a known resistive memory device.

Second and third switching elements N1/N2 and SW2 are disposed under the memory cell array of a cell array region 210, and first switching elements P1*n and SW1 are disposed outside the cell array region 210.

Here, a wire that transfers the global word line signal GX is extended from the gate terminal of the first switching element P1 disposed outside the memory cell array to the gate terminal of the second switching element N1 disposed inside the cell array region 210. To this end, after a unit memory cell is fabricated, a contact plug has to be formed on one side of the unit memory cell. The contact plug has to be connected to a wire extending from the gate terminal of the first switching element P1 to the gate terminal of the second switching is element N1.

That is, since the first switching element P1 is disposed between the unit cell array regions 210, the word lines WL are inevitably cut and formed for each cell array. For this reason, a position tendency occurs between a memory cell close to an area where the contact plug is formed and a memory cell far from the area.

This position tendency results in a word line bouncing phenomenon that changes a distribution of word line voltage levels, as a result, a cell operation characteristic is deteriorated.

### SUMMARY

In an embodiment, a resistive memory device includes a plurality of word lines extended and formed in a first direction; a global word line signal line extended substantially in the first direction, formed substantially in a layer substantially identical with the word lines, and interposed substantially between a designated number of the word lines; a plurality of bit lines extended and formed in a second direction tilted at an angle with the first direction; a plurality of normal cells connected substantially between the word line and the bit line; and a plurality of dummy cells connected substantially between the global word line signal line and the bit line.

In another embodiment, a method of fabricating a resistive memory device includes forming word lines and a global word line signal line, extending substantially in a first direction, substantially on is a semiconductor substrate; forming normal cells substantially over the word line and forming dummy cells substantially over the global word line signal line; forming a bit line in a second direction tilted at an angle with the first direction substantially over the unit memory cells; and disconnecting the dummy cells.

In another embodiment, a method of fabricating a resistive memory device includes forming a word line and a global word line signal line, extending substantially in a first direction, substantially on a semiconductor substrate, forming normal cells substantially over the word line and forming dummy cells substantially over the global word line signal line so that the dummy cells are electrically disconnected, and forming a bit line in a second direction tilted at an angle with the first direction substantially over the unit memory cells.

### BRIEF DESCRIPTION OF THE DRAWINGS

Features, aspects, and various embodiments are described in conjunction with the attached drawings, in which:

FIG. 1 is a schematic diagram of a known resistive memory device;

FIG. 2 shows the construction of a local word line switch;

FIG. 3 a diagram illustrating the disposition of a local word line switch in a known resistive memory device;

FIG. 4 is a diagram illustrating an example of a method of fabricating a resistive memory device according to an embodiment;

FIG. 5 is a diagram illustrating an example of a method of fabricating a resistive memory device according to another embodiment;

FIG. 6 is a diagram illustrating the disposition of the global word line of the resistive memory device according to an embodiment; and

FIG. 7 is an example of a circuit diagram of the resistive memory device according to an embodiment.

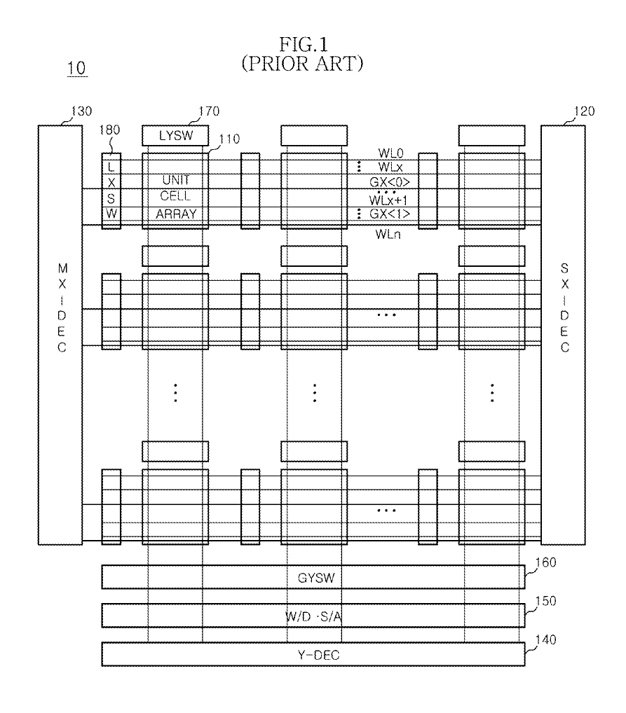

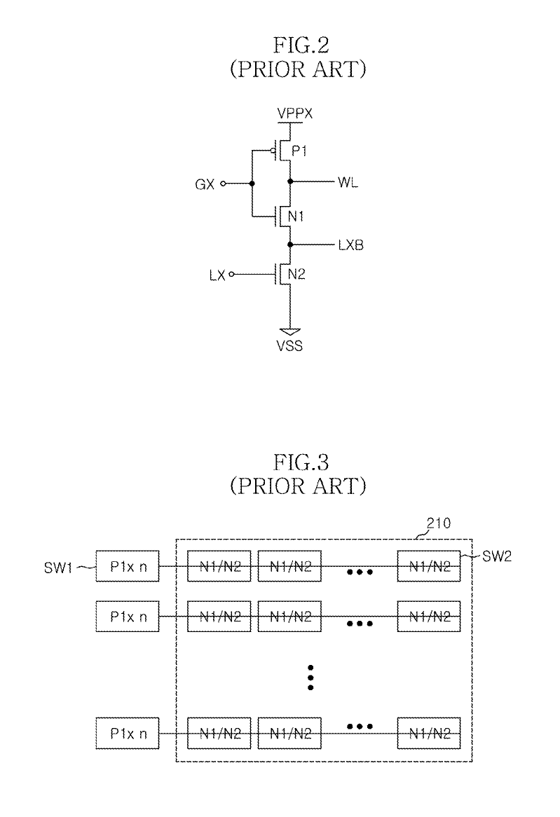

### DETAILED DESCRIPTION

Hereinafter, a resistive memory device and methods of fabricating the same will be described below with reference to the accompanying drawings through various embodiments.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include is a plural form as long as it is not specifically mentioned in a sentence. Furthermore, ‘include/comprise’ or ‘including/comprising’ used in the specification represents that one or more components, steps, operations, and elements exists or are added.

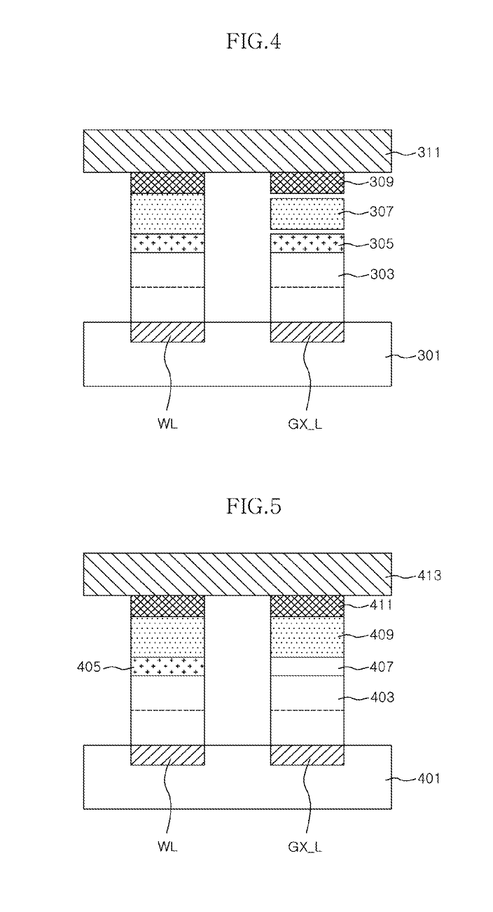

FIG. 4 is a diagram illustrating a method of fabricating a resistive memory device according to an embodiment of the present invention. An example of a phase change memory device is described below.

A global word line signal line GX_L and a word line WL may be formed in substantially the same layer. The method of fabricating a resistive memory device is described below with reference to FIG. 4.

The word line WL and the global word line signal line GX_L may be formed substantially on a semiconductor substrate 301 in a first direction. One global word line signal line GX_L may be formed to substantially cover a designated number of the word lines WL. For example, one global word line signal line GX_L can be formed to cover 8, 16, or 32 word lines.

After the word line WL and the global word line signal line GX_L are formed, an access element 303, a heating electrode 305, a phase change material layer 307, and a top electrode 309 may be sequentially formed so that they may be electrically connected to the word line WL and the global word line signal line GX_L. A bit line 311 may be formed substantially on the top electrode 309 in a direction substantially vertical to the word line WL.

In this state, when a signal of a low level is supplied to the global word line signal line GX_L and a signal of a high level is supplied to the bit line 311, the access element 303, the heating electrode 305, and the phase change material layer 307 that may be formed substantially over the global word line signal line GX_L may be operated like normal cells. Accordingly, dummy cells formed over the global word line signal line GX_L may have to be broken in order to prevent the dummy cells from being operated.

To this end, in the state in which a signal of a low voltage level has been supplied to the global word line signal line GX_L and a signal of a high voltage level has been supplied to the bit line 311, temperature applied to the phase change material layer 307 may be sharply raised so that the phase change material layer 307 may be expanded. When the heating temperature is sharply cooled in this state, the volume of the phase change material layer 307 may be sharply reduced. As a result, cracks may be generated in substantially the top and bottom interfaces of the phase change material layer 307, and thus the top and bottom contact surfaces of the phase change material layer 307 may be disconnected.

Only normal cells formed substantially over the word line WL may be used to store data by breaking the dummy cells formed substantially over the global word line signal line GX_L as described above.

Furthermore, since the global word line signal line GX_L and the word line WL may be formed substantially in the same layer, that is, substantially under a unit cell, a global word line signal may be supplied to the gate terminals of local word line switches even without an additional contact plug.

Accordingly, a word line bouncing phenomenon may be suppressed because the word lines may be formed without disconnecting the word lines.

FIG. 5 is a diagram illustrating an example of a method of fabricating a resistive memory device according to another embodiment. A phase change memory device, for example, is described below.

Referring to FIG. 5, a word line WL and a global word line signal line GX_L may be formed substantially on a semiconductor substrate 401 in a first direction.

An access element 403 may be formed substantially on the word line WL and the global word line signal line GX_L. A heating electrode 405 may be formed substantially on the access element 403. In order to prevent dummy cells over the global word line signal line GX_L from being operated like normal cells, the heating electrode 405 may be formed only on the access element 403 formed substantially on the word line WL in the state in which the top of the access element 403 formed substantially on the global word line signal line GX_L has been masked.

In order to reduce a step between a normal cell and a is dummy cell formed substantially over the word line WL, an insulating film 407 having substantially the same height as the heating electrode 405 may be formed substantially on the access element 403 formed substantially on the global word line signal line GX_L.

A phase change material layer 409 and a top electrode 411 may be sequentially formed substantially over each of the heating electrodes 405 and the insulating films 407. A bit line 413 may be formed in a direction substantially vertical to the word line WL.

In an embodiment, dummy cells may not be electrically conductive because the heating electrode may not be formed in the dummy cells.

Furthermore, the word lines may be formed without disconnecting the word lines because the global word line signal line GX_L may be connected to the gate terminals of switches that form a local word line switch without an additional contact plug.

In an embodiment, where for example in which the heating electrode may not be formed on the dummy cell side has been described, but the embodiment is not limited thereto. In various embodiments, the access element may be substantially removed on the dummy cell side.

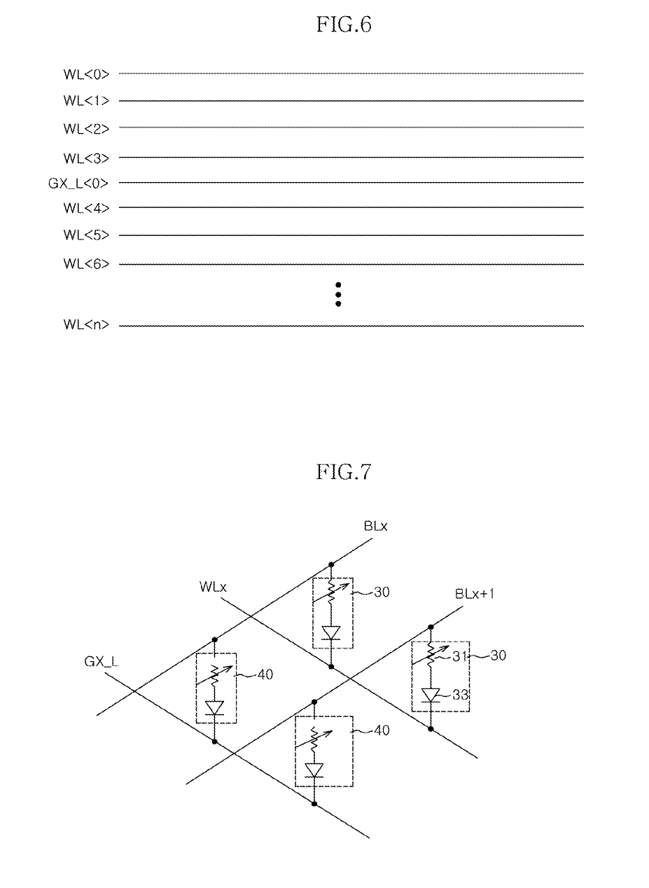

FIG. 6 is a diagram illustrating the disposition of the global word line of the resistive memory device according to an embodiment.

As shown in FIG. 6, the global word line signal line GX_L (i.e., GX_L<0>) may be formed in substantially the same direction as the word lines WL<0:n> (i.e., WL_{—}<0>, WL_{—}<1>, WL_{—}<2>, WL_{—}<3>, WL_{—}<4>, WL_{—}<5>, WL_{—}<6>, WL_<n>). In particular, the global word line signal line GX_L may be formed in substantially the same layer as word lines WL<0:n>.

FIG. 7 is an example of a circuit diagram of the resistive memory device according to an embodiment.

Referring to FIG. 7, the resistive memory device according to various embodiments may include a plurality of word lines WL (i.e., WLx) extended and formed in substantially a first direction, a global word line signal line GX_L formed in substantially the same layer as the word lines, disposed substantially between a designated number of the word lines WL, and extended and formed substantially in the first direction, a plurality of bit lines BL (i.e., BLx, BLx+1) extended and formed substantially in a second direction tilted at a specific angle with the first direction, a plurality of normal cells 30 connected substantially between the word line WL and the bit lines BL, and a plurality of dummy cells 40 connected substantially between the global word line signal line GX_L and the bit lines BL.

The dummy cells 40 may be formed in the state in which they may not be operated as normal cells. For example, after the dummy cells 40 and the normal cells 30 are formed using substantially the same process, the volume of the phase change material layer may be sharply increased and then sharply reduced so that the dummy cells 40 may be electrically disconnected. In another example, the heating electrode or another element may not be formed in the process of fabricating the dummy cells 40 and the normal cells 30 together so that the dummy cells 40 may not be electrically conductive.

As described above, in various embodiments, word lines can be formed without disconnection because the global word line signal line GX_L may be formed in substantially the same layer as the word lines. Accordingly, a read margin can be improved because a word line bouncing phenomenon is suppressed.

The improvement of a read margin for a unit memory cell enables resolution to be controlled in a read operation. Accordingly, the degree of integration of cells per unit area can be improved because a memory cell can be operated as a multi-level cell (MLC) not a single level cell (SLC).

As a result, added value is possible because a memory cell having a twice or higher capacity can be formed in the same chip size.

While certain embodiments have been described above, it will be understood to those skilled in the art that the embodiments described are by way of example only. Accordingly, the device and methods described herein should not be limited based on the described embodiments. Rather, the embodiments have been disclosed above for illustrative purposes. Those skilled in the art will appreciate that various modifications, additions and substitutions are possible, without departing from the scope and spirit of the inventive is concept as disclosed in the accompanying claims.

What is claimed is:

1. A resistive memory device, comprising:
a plurality of word lines extended and formed in a first direction;
a global word line signal line extended substantially in the first direction, formed substantially in a layer substantially identical with the word lines, and interposed substantially between a designated number of the word lines;
a plurality of bit lines extended and formed in a second direction tilted at an angle with the first direction;
a plurality of normal cells connected substantially between the word line and the bit line; and
a plurality of dummy cells connected substantially between the global word line signal line and the bit line.

2. The resistive memory device according to claim 1, wherein the dummy cells are electrically disconnected.

3. The resistive memory device according to claim 1, further comprising a local word line switch configured to control electric potential of the word line in response to a local word line signal and a global word line signal.

4. The resistive memory device according to claim 3, wherein the local word line switch comprises:
a first switching element configured to supply a high voltage to the word line;
a second switching element in series connected to the first switching element and configured to form or block a current path to the normal cell; and
a third switching element connected in series between the second switching element and a ground terminal.

5. The resistive memory device according to claim 4, wherein the first switching element supplies a high voltage to the word line in response to the global word line signal.

6. The resistive memory device according to claim 4, wherein the second switching element forms or blocks a current path to the normal cell in response to the global word line signal.

7. The resistive memory device according to claim 4, wherein the third switching element is driven in response to the local word line signal.

8. A method of fabricating a resistive memory device, comprising:
forming word lines and a global word line signal line, extending substantially in a first direction, substantially on a semiconductor substrate;
forming normal cells substantially over the word line and forming dummy cells substantially over the global word line signal line;
forming a bit line in a second direction tilted at an angle with the first direction substantially over the unit memory cells; and
disconnecting the dummy cells.

9. The method according to claim 8, wherein:
the forming of the normal cells and the dummy cells comprises sequentially forming an access element, a heating electrode, a phase change material layer, and a top electrode substantially over each of the word line and the global word line signal line.

10. The method according to claim 9, wherein the disconnecting of the dummy cells comprises breaking interfaces of the phase change material layer formed over the global word line signal line by supplying a voltage to the global word line signal line and the bit line.

11. The method according to claim 10, wherein the breaking of the phase change material layer comprises increasing a volume of the phase change material layer and then reducing the volume of the phase change material layer.

12. The method according to claim 11, wherein, the volume of the phase change material layer is sharply increased and the volume of the phase change material layer is sharply reduced.

13. A method of fabricating a resistive memory device, comprising:
forming a word line and a global word line signal line, extending substantially in a first direction, substantially on a semiconductor substrate;
forming normal cells substantially over the word line and forming dummy cells substantially over the global word line signal line so that the dummy cells are electrically disconnected; and
forming a bit line in a second direction tilted at an angle with the first direction substantially over the unit memory cells.

14. The method according to claim 13, wherein the forming of the dummy cells comprises:
forming an access element substantially on the global word line signal line;
forming an insulating film substantially on the access element; and
forming a phase change material layer substantially on the insulating film.

15. The method according to claim 13, wherein the forming of the dummy cells comprises:
forming an insulating film substantially on the global word line signal line;
forming a heating electrode substantially on the insulating film; and
forming a phase change material layer substantially on the heating electrode.
